(19) United States
(12) Patent Application Publication
(10) Pub. No.: US 2014/0319700 A1
(43) Pub. Date: Oct. 30, 2014

(54) SEMICONDUCTOR DEVICE AND METHOD OF MANUFACTURING SAME

(71) Applicant: Kabushiki Kaisha Toshiba, Minato-ku (JP)

(72) Inventor: Takeshi KOSHIBA, Yokkaichi-shi (JP)

(73) Assignee: Kabushiki Kaisha Toshiba, Minato-ku (JP)

(21) Appl. No.: 14/132,203

(22) Filed: Dec. 18, 2013

(30) Foreign Application Priority Data
Apr. 24, 2013 (JP) 2013-091724

(51) Int. Cl. H01L 21/306; H01L 23/528

(52) U.S. Cl. CPC H01L 21/30604; H01L 23/528
USPC 257/775; 438/694

(57) ABSTRACT

In one embodiment, a method of manufacturing a semiconductor device includes forming one or more first patterns and one or more second patterns adjacent to the first patterns on a substrate, each first pattern including a linear portion extending in a first direction, and each second pattern including first and second linear portions extending in the first direction and a connection portion connecting end portions of the first and second linear portions with each other. The method further includes forming a resist layer on the first and second patterns. The method further includes forming a resist opening in the resist layer so that at least a part of a contour line of the resist opening is a curved line and the curved line overlaps the second patterns. The method further includes dividing the second patterns into the first and second linear portions by etching using the resist layer.

### CROSS REFERENCE TO RELATED APPLICATION

This application is based upon and claims the benefit of priority from the prior Japanese Patent Application No. 2013-91724, filed on Apr. 24, 2013, the entire contents of which are incorporated herein by reference.

### FIELD

Embodiments described herein relate to a semiconductor device and a method of manufacturing the same.

### BACKGROUND

A pattern having a width less than lithography resolution limit can be formed, for example, by etching using a sidewall pattern. However, the sidewall pattern or an interconnect pattern formed by using the sidewall pattern as a mask has a closed loop in some cases. In these cases, a lithography process and an etching process are required to cut the closed loop. Furthermore, when a resist mask for cutting the closed loop is formed, it is necessary to form a resist opening in the resist mask so as not to etch a pattern which is near the loop-cut target pattern. At this time, if a position where the resist opening is formed is deviated toward the loop-cut target pattern, a portion of the loop-cut target pattern is possibly left as a long minute line after the etching. This may lead to degradation in yield or reliability of a semiconductor device and to contamination of a semiconductor manufacturing line.

### BRIEF DESCRIPTION OF THE DRAWINGS

FIGS. 1A to 10B are sectional views and plan views showing a method of manufacturing a semiconductor device of a first embodiment;

FIG. 11 is a plan view showing a detail of the method of manufacturing the semiconductor device of the first embodiment;

FIGS. 12 and 13 are plan views showing a method of manufacturing a semiconductor device of a comparative example;

FIG. 14 is a plan view showing a method of manufacturing a semiconductor device of a modification of the first embodiment; and

FIGS. 15A to 19B are sectional views and plan views showing a method of manufacturing a semiconductor device of a second embodiment.

### DETAILED DESCRIPTION

Embodiments will now be explained with reference to the accompanying drawings.

In one embodiment, a method of manufacturing a semiconductor device includes forming one or more first patterns and one or more second patterns adjacent to the first patterns on a semiconductor substrate, each first pattern including a linear portion extending in a first direction, and each second pattern including first and second linear portions extending in the first direction and a connection portion connecting an end portion of the first linear portion and an end portion of the second linear portion with each other. The method further includes forming a resist layer on the first and second patterns. The method further includes forming a resist opening in the resist layer so that at least a part of a contour line of the resist opening is a curved line and the curved line overlaps the second patterns. The method further includes dividing the second patterns into the first and second linear portions by etching using the resist layer.

### First Embodiment

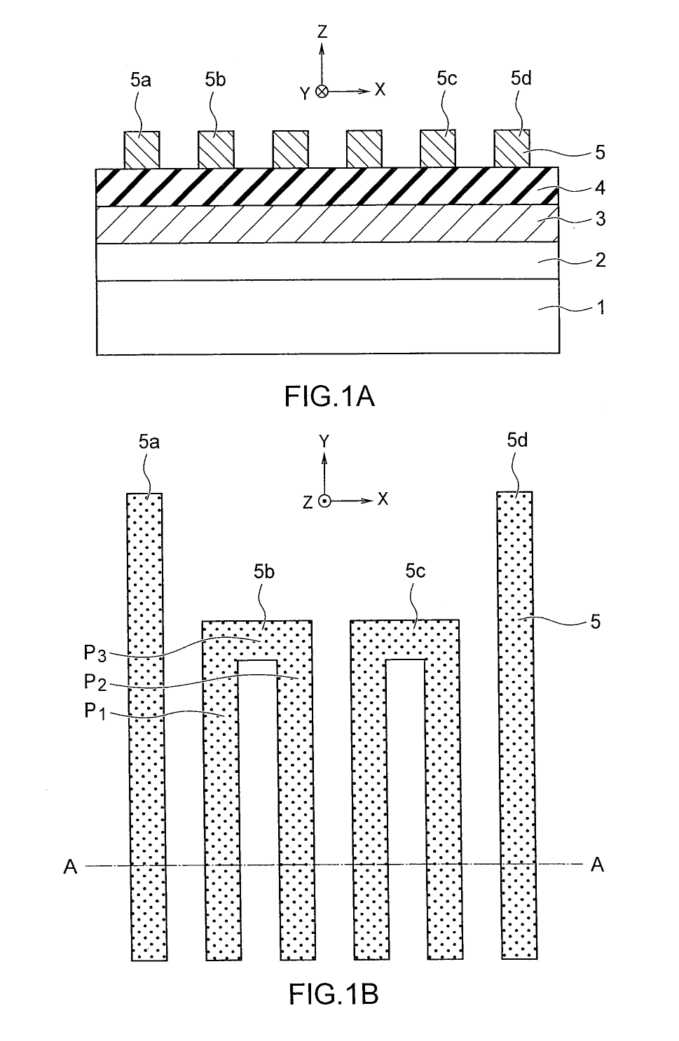

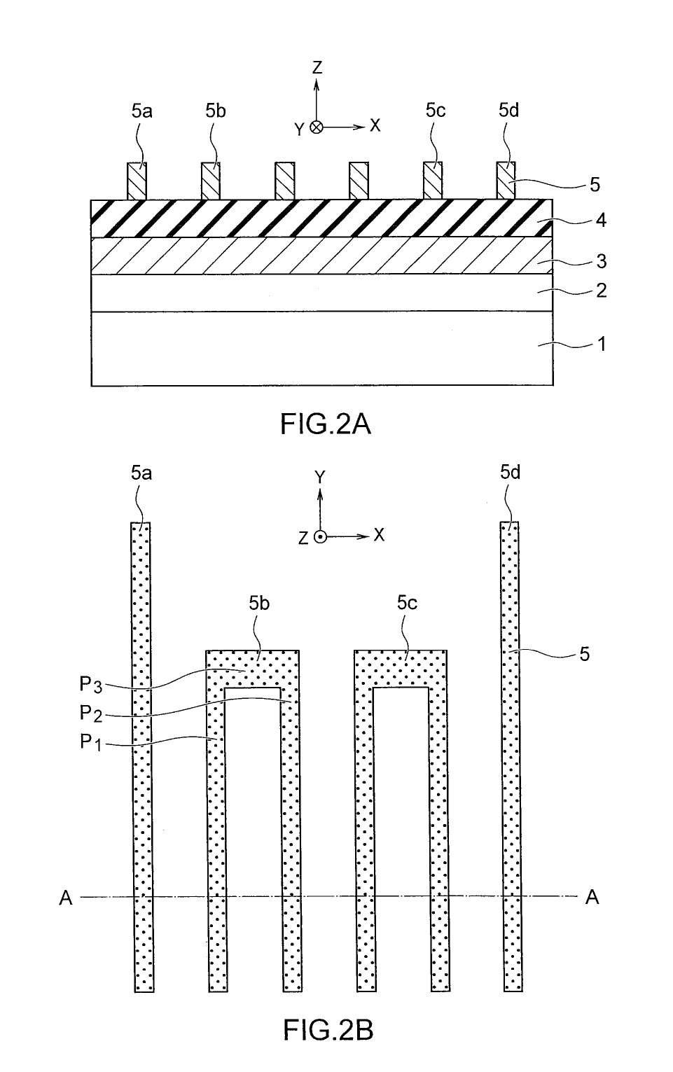

FIGS. 1A to 10B are sectional views and plan views showing a method of manufacturing a semiconductor device of a first embodiment. FIG. 1A shows a cross section taken along the line A-A of FIG. 1B (the same applies to FIGS. 2A to 10B).

First, as shown in FIGS. 1A and 1B, a base layer 2, an interconnect material 3 as a workpiece layer, a mask material 4, and a core material 5 are sequentially formed on a semiconductor substrate 1, and the core material 5 is processed into core material patterns 5a to 5d by lithography and etching.

The semiconductor substrate 1 is, for example, a silicon substrate. The base layer 2 is, for example, a silicone oxide layer. The interconnect material 3 is, for example, a copper (Cu) layer, a tungsten (W) layer, or an aluminum (Al) layer. The mask material 4 is, for example, a silicone oxide layer. The core material 5 is, for example, an amorphous silicon layer.

FIGS. 1A and 1B indicate X and Y directions which are parallel with a surface of the semiconductor substrate 1 and perpendicular to each other, and a Z direction perpendicular to the surface of the semiconductor substrate 1. The Y and X direction are examples of first and second directions, respectively. In this specification, +Z direction is treated as an upward direction and −Z direction is treated as a downward direction. For example, a positional relationship between the semiconductor substrate 1 and the base layer 2 is expressed that the semiconductor substrate 1 is positioned below the base layer 2.

The core material 5 is processed into first core material patterns 5a and 5d, and second core material patterns 5b and 5c adjacent to the first core material patterns 5a and 5d. Each first core material pattern 5a, 5a includes a linear portion extending in the Y direction. Each second core material pattern 5b, 5c includes first and second linear portions P₁ and P₂ extending in the Y direction, and a connection portion P₃ connecting an end portion of the first linear portion P₁ and an end portion of the second linear portion P₂ with each other. The core material patterns 5a to 5d in the present embodiment have a constant line width close to the resolution limit of lithography (e.g., 40 nm).

Each second core material pattern 5b, 5c includes not only the connection portion P₃ which connects one end portion of the first linear portion P₁ and one end portion of the second linear portion P₂ with each other, but also includes another connection portion (not shown) which connects the other end portion of the first linear portion P₁ and the other end portion of the second linear portion P₂ with each other, so that each second core material pattern 5b, 5c has a shape of a closed loop. These connection portions have a function to prevent a pattern collapse of the second core material patterns 5b and 5c, for example.

The linear portions of the first core material patterns 5a and 5d are longer than the first and second linear portions P₁ and P₂ of the second core material patterns 5b and 5c. Each first core material patterns 5a, 5d may include only one linear portion, or may have a shape of a closed loop similar to the second core material patterns 5b and 5c.

Next, as shown in FIGS. 2A and 2B, slimming is carried out to slim the core material patterns 5a to 5d by anisotropic etching or the like. The slimming in the present embodiment is carried out so that the core material patterns 5a to 5d have a line width about half the resolution limit of lithography (e.g., 20 nm). Note that the line width of the connection portion P₃ in the present embodiment is not made smaller by the slimming.

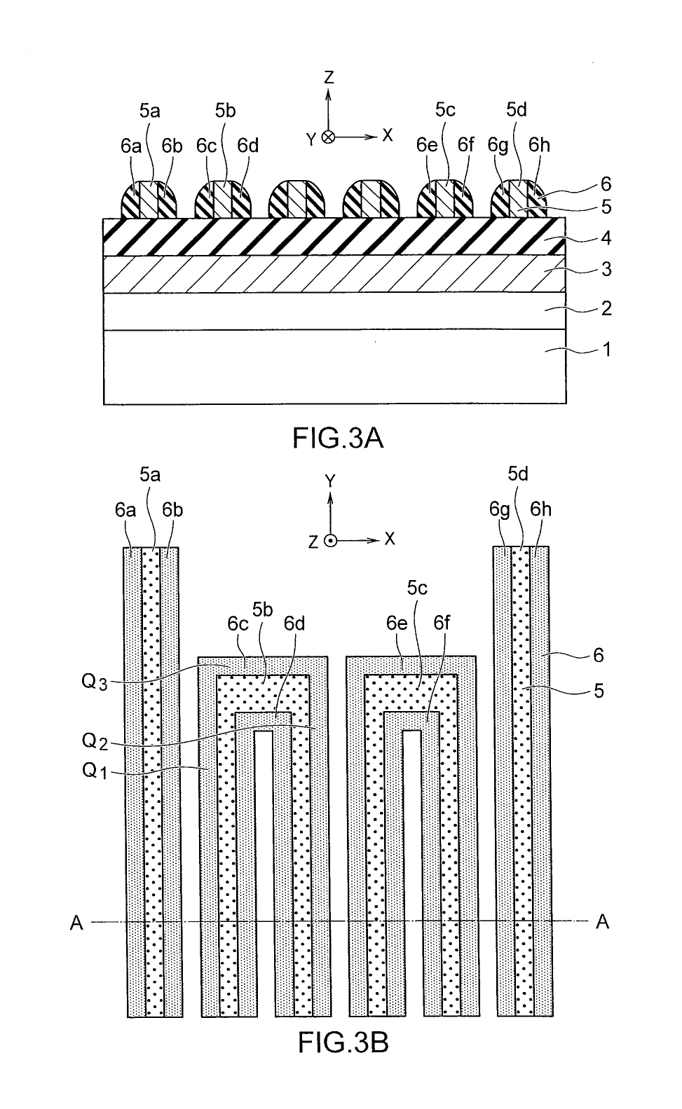

Next, as shown in FIGS. 3A and 3B, a sidewall material 6 is deposited on the entire surface of the semiconductor substrate 1, and the sidewall material 6 is processed by anisotropic etching or the like. As a result, sidewall patterns 6a to 6h are formed on side surfaces of the core material patterns 5a to 5b.

The sidewall material 6 in the present embodiment is formed of a material having a high etching selectivity with respect to the core material 5. For example, if the core material 5 is the amorphous silicon layer, an example of the sidewall material 6 is a silicon nitride layer.

The sidewall material 6 is processed into first sidewall patterns 6a, 6b, 6g and 6h, and second sidewall patterns 6c to 6f adjacent to the first sidewall patterns 6a, 6b, 6g and 6h. Each first sidewall patterns 6a, 6b, 6g, 6h includes a linear portion extending in the Y direction. Each second sidewall patterns 6c, 6d, 6e, 6f includes first and second linear portions Q₁ and Q₂ extending in the Y direction, and a connection portion Q₃ connecting an end portion of the first linear portion Q₁ and an end portion of the second linear portion Q₂. The sidewall patterns 6a to 6h in the present embodiment have a constant line width about half the resolution limit of lithography (e.g., 20 nm).

Similarly to the second core material patterns 5b and 5c, each second sidewall pattern 6c, 6d, 6e, 6f includes the connection portion Q₃ and another connection portion which is not shown, and therefore has a shape of a closed loop.

Furthermore, the linear portions of the first sidewall patterns 6a, 6b, 6g and 6h are longer than the first and second linear portions Q₁ and Q₂ of the second sidewall patterns 6c to 6f.

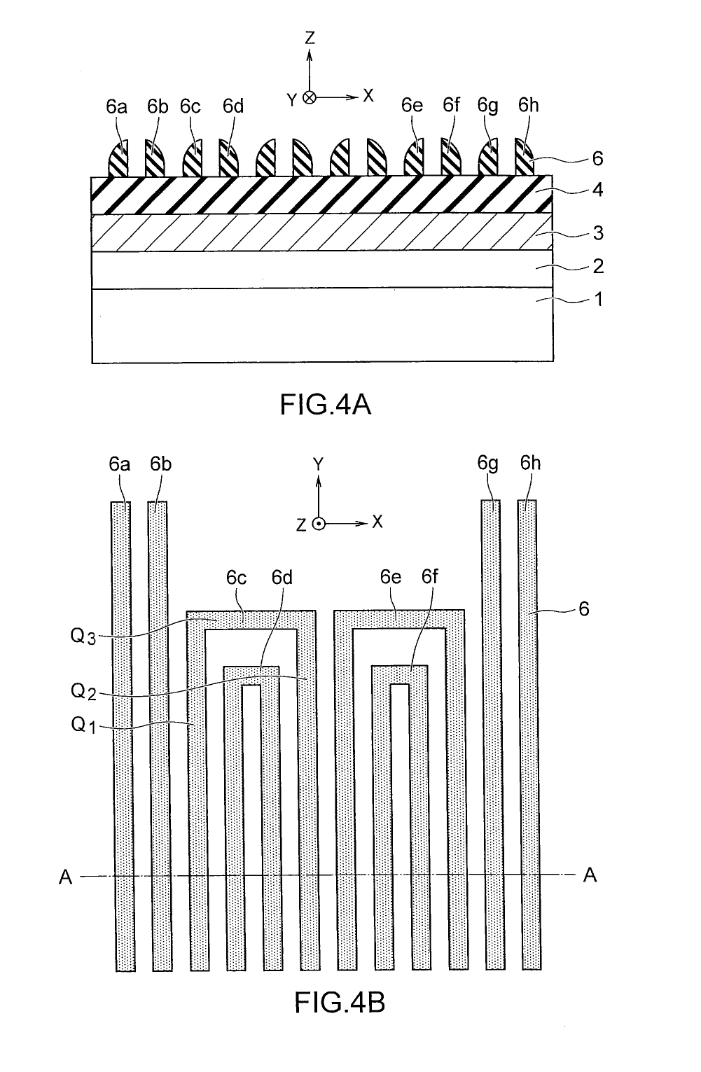

Next, as shown in FIGS. 4A and 4B, the core material patterns 5a to 5d are removed by dry etching such as chemical dry etching (CDE) with the sidewall patterns 6a to 6h being left.

The first and second sidewall patterns 6a to 6h obtained in this way are examples of the first and second patterns, respectively. In addition, the second sidewall patterns 6c and 6e are examples of a nearest second pattern which is nearest to the first sidewall patterns 6a, 6b, 6g and 6h among the second sidewall patterns 6c to 6f. On the other hand, the first sidewall patterns 6b and 6g are examples of a nearest first pattern which is nearest to the second sidewall patterns 6c to 6f among the first sidewall patterns 6a, 6b, 6g and 6h.

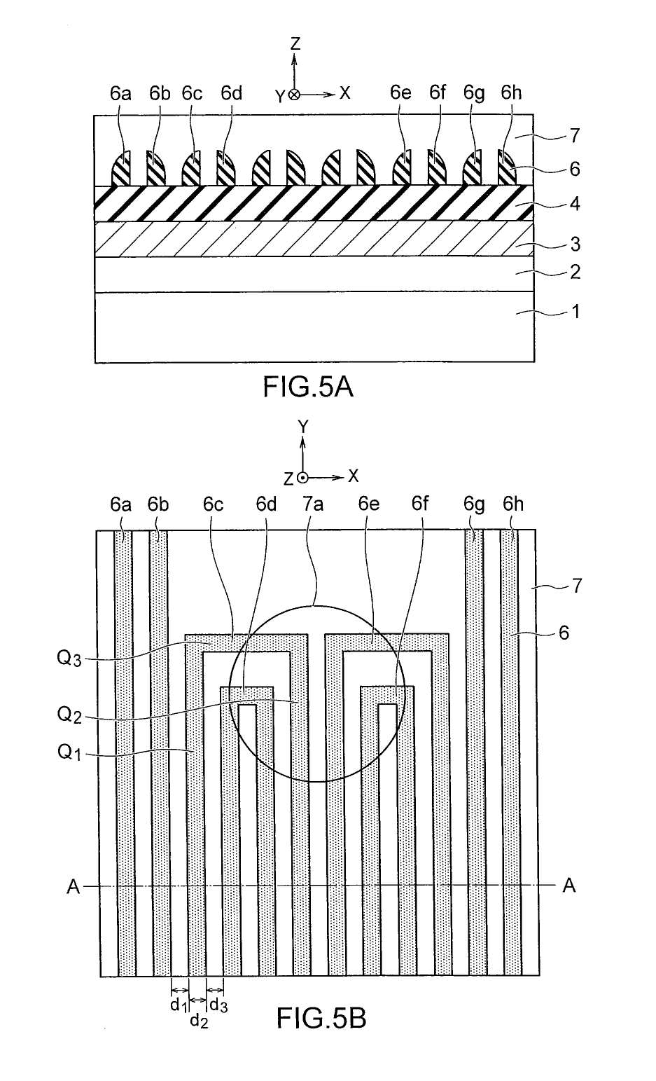

Next, as shown in FIGS. 5A and 5B, a resist layer 7 is formed on the entire surface of the semiconductor substrate 1 to cover the sidewall patterns 6a to 6h with the resist layer 7. As shown in FIGS. 5A and 5B, a circular resist opening 7a is then formed in the resist layer 7.

The resist opening 7a in the present embodiment is an example of a resist opening in which at least a part of a contour line of the resist opening is a curved line. In the present embodiment, since the shape of the contour line of the resist opening 7a is a circle (true circle), all the contour line of the resist opening 7a is the curved line.

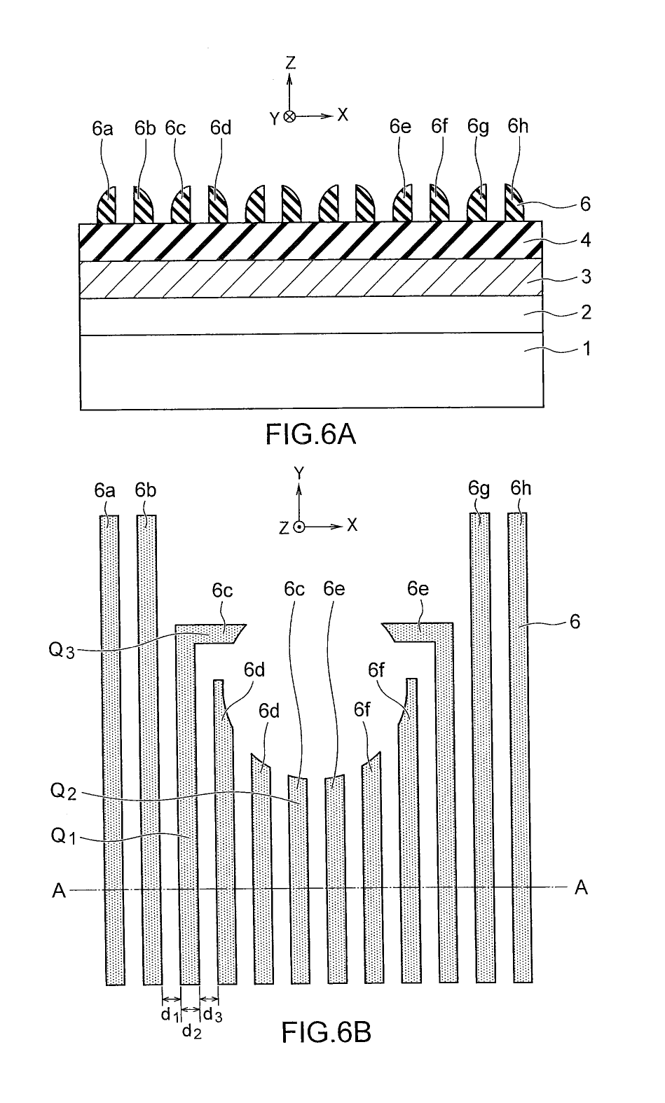

The resist opening 7a is formed so that its contour line (curved line) overlaps the second sidewall patterns 6c to 6f. As a result, each second sidewall pattern 6c, 6d, 6e, 6f is etched to have a curved cut edge by the etching described later (see FIGS. 6A and 6B).

Furthermore, the resist opening 7a is formed so that its contour line does not overlap the first sidewall patterns 6a, 6b, 6g and 6h. Therefore, the first sidewall patterns 6a, 6b, 6g and 6h are not etched in the etching described later (see FIGS. 6A and 6B).

The resist opening 7a in the present embodiment is formed so that its contour line overlaps the connection portion Q₃ of at least one of the second sidewall patterns 6c to 6f. For example, the resist opening 7a in FIG. 5B is formed so that its contour line overlaps the connection portions Q₃ of the nearest second sidewall patterns 6c and 6e. The resist opening 7a in FIG. 5B is also formed so that its contour line overlaps the second linear portions Q₂ of the nearest second sidewall patterns 6c and 6e and does not overlap the first linear portions Q₂ of the nearest second sidewall patterns 6c and 6e. Furthermore, the contour line of the resist opening 7a in the present embodiment is formed to overlap two portions of each second sidewall pattern 6c, 6d, 6e, 6f.

In the present embodiment, when the resist opening 7a is formed in the vicinity of the connection portions Q₃ of the second sidewall patterns 6c to 6f, another resist opening is also formed in the vicinity of other connection portions of the second sidewall patterns 6c to 6f. Closed loops of the second sidewall patterns 6c to 6f are cut by etching using the resist layer 7 having these resist openings.

A character “d₁” represents a width of a space between the linear portion of the nearest first sidewall pattern 6b and the first linear portion Q₁ of the nearest second sidewall pattern 6c. A character “d₂” represents a line width of the first linear portion Q₁ of the nearest second sidewall pattern 6c. A character “d₃” represents a width of a space between the first linear portions Q₁ of the second sidewall patterns 6c and 6d. These widths d₁ to d₃ may have the same value, or may have different values from each other. These widths d₁ to d₃ will be referred in the description of a margin for a position adjustment deviation of lithography and the like later.

Next, as shown in FIGS. 6A and 6B, the closed loops of the second sidewall patterns 6c to 6f are cut by etching using the resist layer 7. As a result, the second sidewall patterns 6c to 6f are divided into the first linear portions Q₁ and the second linear portions Q₂.

In the present embodiment, at least one of the second sidewall patterns 6c to 6f is divided into a first portion including the first linear portion Q₁ and the connection portion Q₃, and a second portion including the second linear portion Q₂. In FIG. 6B, each nearest second sidewall pattern 6c, 6e is divided into the first portion including the first linear portion Q₁ and the connection portion Q₃, and the second portion including the second linear portion Q2. However, in each nearest second sidewall pattern 6c, 6e, since the connection portion Q₃ is partially etched, the length of the connection portion Q₃ included in the second portion after the dividing is shorter than the length of the connection portion Q₃ before the dividing.

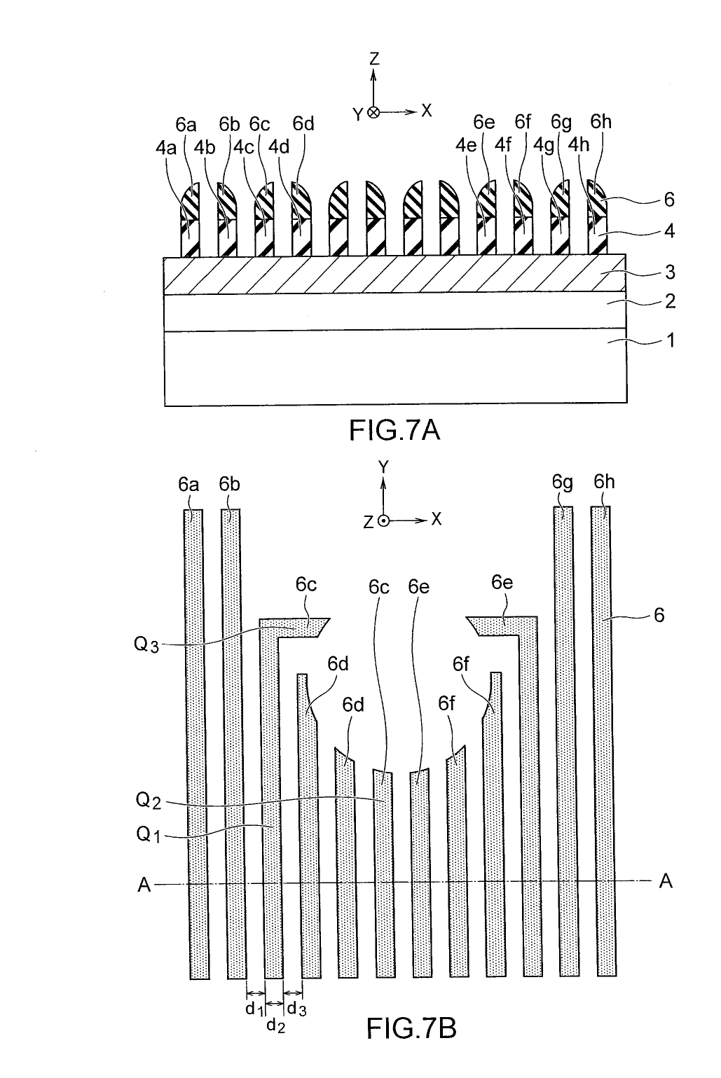

Next, as shown in FIGS. 7A and 7B, the mask material 4 is etched by using the sidewall patterns 6a to 6h as a mask. As a result, the mask material 4 is processed into mask patterns 4a to 4h having the same shape as the sidewall patterns 6a to 6h. Etching of the mask material 4 is carried out by dry etching using a gas such as CF₄ or CHF₃, for example.

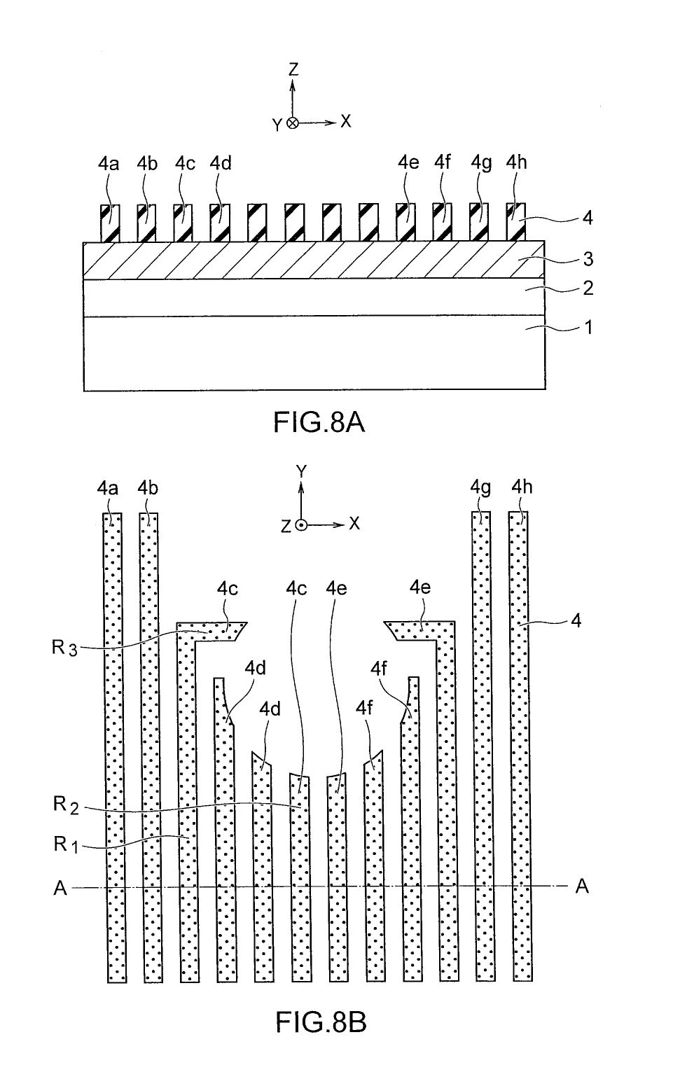

Next, as shown in FIGS. 8A and 8B, the sidewall patterns 6a to 6h are removed by wet etching or the like. FIGS. 8A and 8B show first mask patterns 4a, 4b, 4g and 4h, and second mask patterns 4c to 4f adjacent to the first mask patterns 4a, 4b, 4g and 4h. Each first mask pattern 4a, 4b, 4g, 4h includes a linear portion. Each second mask pattern 4c, 4d, 4e, 4f includes first and second linear portions R₁ and R₂ and a connection portion R₃.

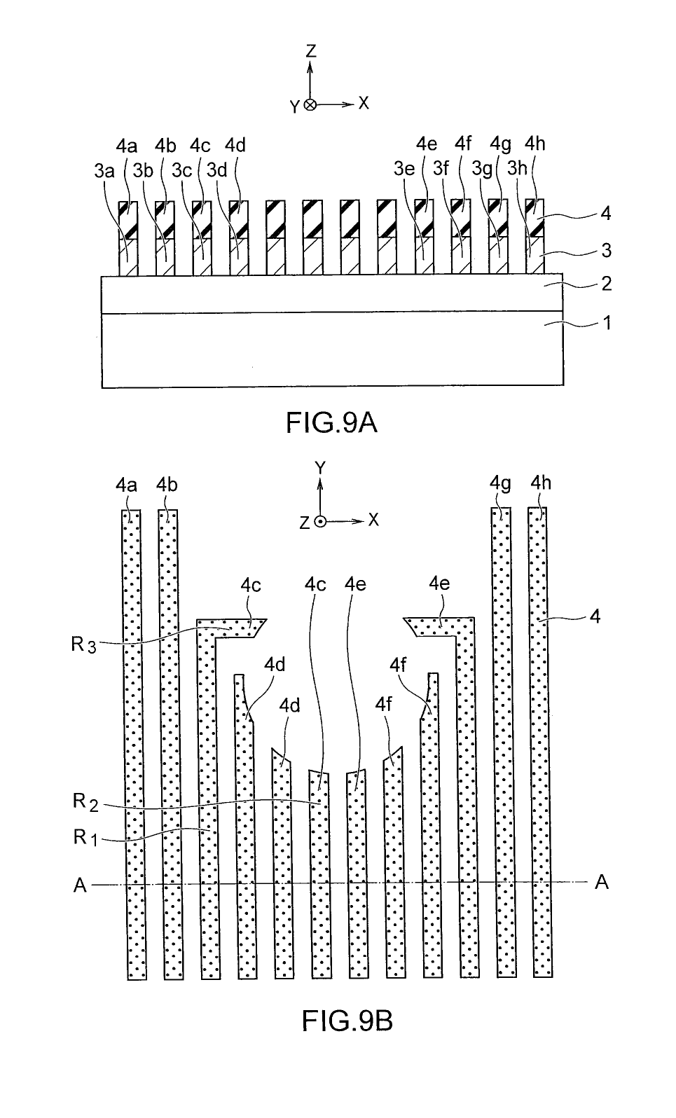

Next, as shown in FIGS. 9A and 9B, the interconnect material 3 is etched by using the mask patterns 4a to 4h as a mask. As a result, the interconnect material 3 is processed into interconnect patterns 3a to 3h having the same shape as the mask patterns 4a to 4h.

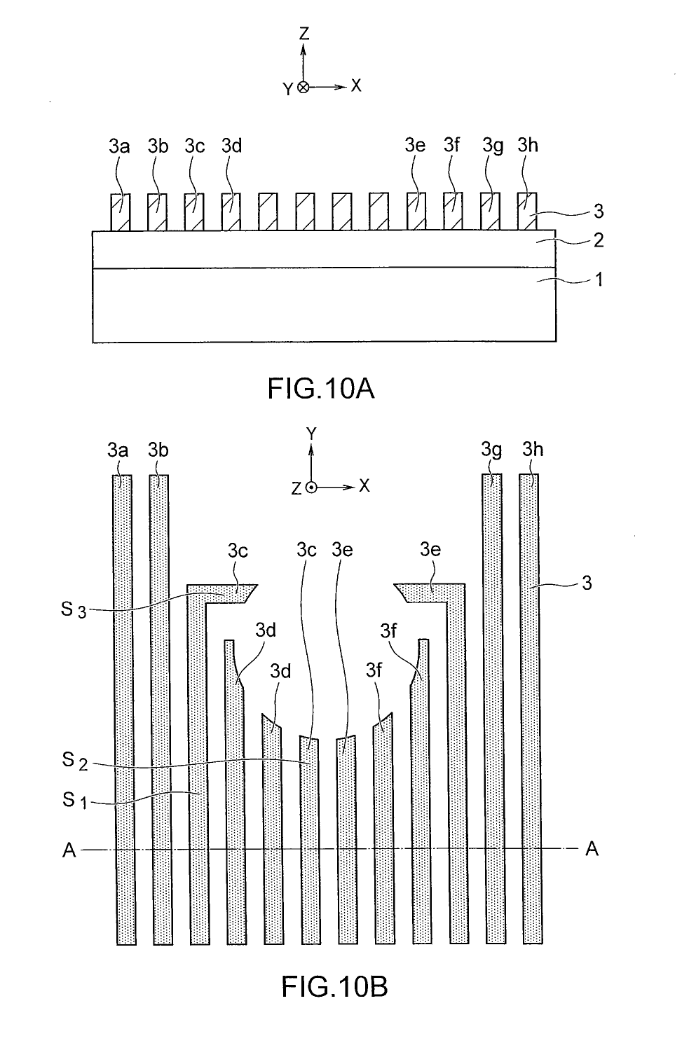

Next, as shown in FIGS. 10A and 10B, the mask patterns 4a to 4h are removed by wet etching or the like. FIGS. 10A and 10B show first interconnect patterns 3a, 3b, 3g and 3h, and second interconnect patterns 3c to 3f adjacent to the first interconnect patterns 3a, 3b, 3g and 3h. Each first interconnect pattern 3a, 3b, 3g, 3h includes a linear portion. Each second interconnect pattern 3c, 3d, 3e, 3f includes first and second linear portion S₁ and S₂ and a connection portion S₃. In this way, the interconnect patterns 3a to 3h having the line width less than the resolution limit of lithography are formed.

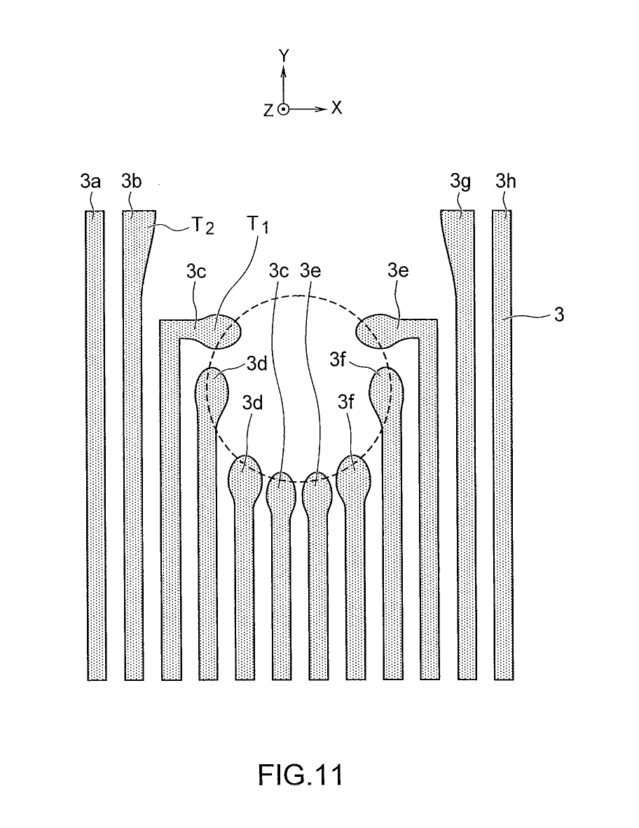

The interconnect patterns 3a to 3h actually have shapes as shown in FIG. 11 depending on a processing transformation difference in etching. FIG. 11 is a plan view showing a detail of the method of manufacturing the semiconductor device of the first embodiment.

As shown in FIG. 11, a width of an end portion T₁ of each second interconnect pattern 3c, 3d, 3e, 3f is larger than widths of portions of each second interconnect pattern 3c, 3d, 3e, 3f other than the end portion T₁. Furthermore, each nearest first interconnect pattern 3b, 3g includes a region T₂ whose line width is expanded in a direction of the second interconnect patterns 3c to 3f in the vicinity of the connection portion S₃ of each nearest second interconnect pattern 3c, 3e.

A circle of dashed line shown in FIG. 11 shows a region where the resist opening 7a was formed. The end portions T₁ of the second interconnect patterns 3c to 3f in FIG. 11 are substantially positioned on this circle similar to the end portions of the interconnect patterns 3c to 3f in FIG. 10B.

The end portions T₁ of the second interconnect patterns 3c to 3f may be used as regions for forming contact plugs. In this case, the contact plugs are formed on the end portions T₁ of the second interconnect patterns 3c to 3f.

### (1) Comparison between First Embodiment and Comparative Example

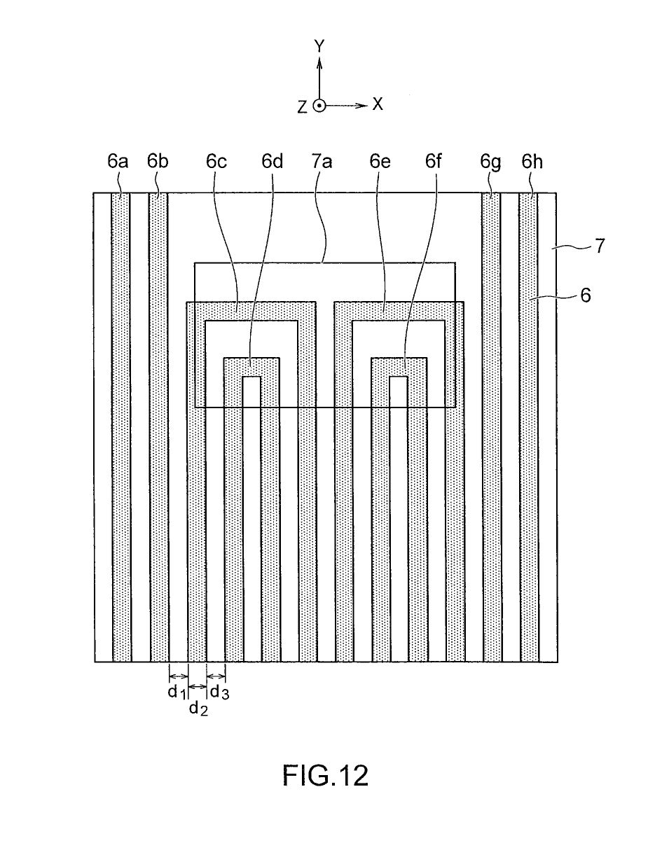

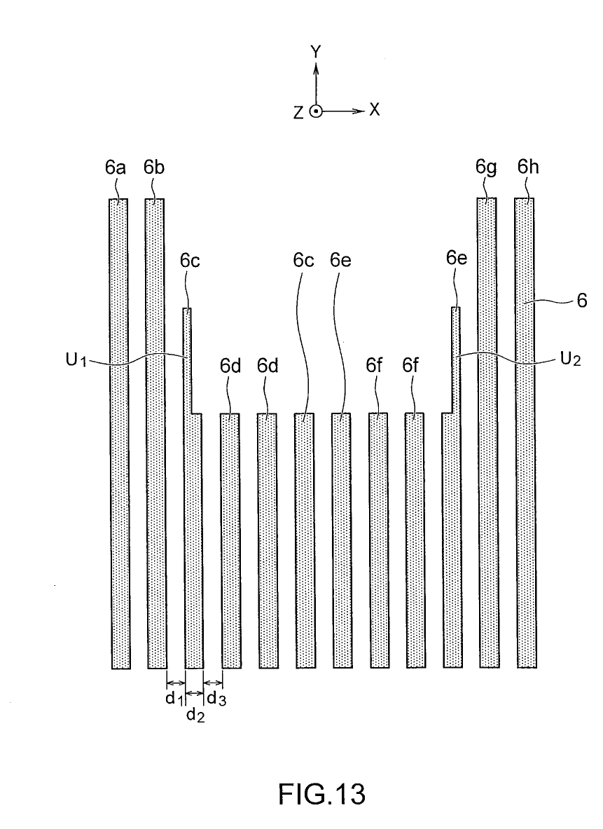

FIGS. 12 and 13 are plan views showing a method of manufacturing a semiconductor device of a comparative example. Steps in FIGS. 12 and 13 correspond to the steps in FIGS. 5A and 5B and FIGS. 6A and 6B, respectively.

The resist layer 7 in FIG. 12 includes a rectangle resist opening 7a for cutting closed loops of the second sidewall patterns 6c to 6f. This resist opening 7a is desirably formed so that sides of the rectangle parallel with the Y direction are put between the nearest first sidewall patterns 6b and 6g and the nearest second sidewall patterns 6c and 6e. However, the sides of the resist opening 7a in FIG. 12 are put on the nearest second sidewall patterns 6c and 6e due to the position adjustment deviation and the like of lithography.

Therefore, if the second sidewall patterns 6c to 6f are etched by using this resist layer 7, portions of the nearest second sidewall patterns 6c and 6e are left as long minute lines U₁ and U₂ after the etching as shown in FIG. 13.

In general, the line widths of the sidewall patterns 6a to 6h are set to less than the resolution limit of lithography. Accordingly, the minute lines U₁ and U₂ have line widths smaller than the resolution limit of lithography in many cases. The minute lines U₁ and U₂ in these cases have a high risk of bringing about pattern missing in the dry etching step or chemical treatment step.

In order to prevent the minute lines U₁ and U₂ from being generated, the resist opening 7a is necessary to be formed so that the sides of the resist opening 7a parallel with the Y direction are put on a space between the nearest first sidewall patterns 6b and 6g and the nearest second sidewall patterns 6c and 6e. However, a margin for adjustment of lithography in this case is only half the space width “d₁”. In general, since the width “d₁” is also set to less than the resolution limit of lithography, it is difficult to control the lithography adjustment with this margin.

Therefore, in the case of using the rectangle resist opening 7a, it is difficult to prevent the minute lines U₁ and U₂ from being generated. Generations of the pattern missing due to the minute lines U₁ and U₂ cause dusts to be left on a wafer or a process treatment chamber to be contaminated, which may lead to degradation in yield or reliability of the semiconductor device and contamination of a semiconductor manufacturing line.

On the other hand, the circular resist opening 7a is used in the present embodiment as shown in FIGS. 5A and 5B. The contour line of the circular resist opening 7a does not include a straight line parallel with the Y direction, which makes it possible to prevent the long minute line from being generated in the present embodiment unlike the comparative example no matter where the resist opening 7a is arranged. Therefore, according to the present embodiment, the pattern missing due to such a minute line is prevent from being generated, allowing to suppress degradation in yield or reliability of the semiconductor device and contamination of a semiconductor manufacturing line.

In addition, the position and size of the resist opening 7a in the present embodiment are desirably set so that at least a part of the connection portions Q₃ of the nearest second sidewall patterns 6c and 6e is left after the etching. This can be achieved by, as shown in FIGS. 5A and 5B, arranging the resist opening 7a so that the contour line of the resist opening 7a overlaps the connection portions Q₃ of the nearest second sidewall patterns 6c and 6e.

In this case, if an error of the position or size of the resist opening 7a is smaller than d₁+d₂+d₃, the nearest first sidewall patterns 6b and 6g can be prevented from being accidentally etched. In other words, the margin for adjustment of lithography in this case is d₁+d₂+d₃. Therefore, according to the present embodiment, the margin for adjustment of lithography can be sufficiently secured.

In the case where at least a part of the connection portions Q₃ of the nearest second sidewall patterns 6c and 6e is left after the etching, expansions at the end portions T₁ of the nearest second interconnect patterns 3c and 3e shown in FIG. 11 are generated not in the first linear portions S₁ but in the connection portions S₃. If these expansions are generated in the first linear portions S₁, the end portions T₁ are possibly shorted with the regions T₂. Therefore, the leaving of at least a part of the connection portions Q₃ after the etching also leads to an advantage of being able to suppress such a short.

### (2) Modification of First Embodiment

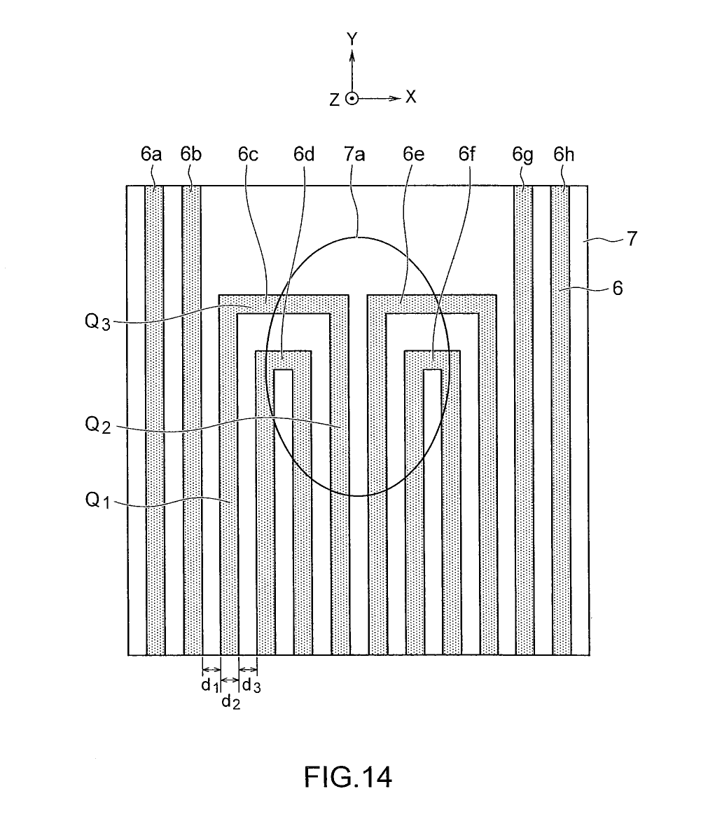

FIG. 14 is a plan view showing a method of manufacturing a semiconductor device of a modification of the first embodiment. A step in FIG. 14 corresponds to the step in FIGS. 5A and 5B.

The contour line of the resist opening 7a in FIG. 14 has a shape of an ellipse. In addition, this ellipse has a radius in the Y direction set longer than a radius in the X direction. Therefore, the radius in the Y direction corresponds to a major radius, and the radius in the X direction corresponds to a minor radius.

In this manner, the shape of the contour line of the resist opening 7a in the present embodiment may be the circle or the ellipse. However, in order to improve dimensional precision of the sidewall patterns 6a to 6h, the shape of the contour line of the resist opening 7a is desirably the circle rather than the ellipse. The dimensional precision of the sidewall patterns 6a to 6h can be improved by, for example, reducing a difference between the major radius and the minor radius of the resist opening 7a of the ellipse to bring the ellipse close to a circle.

Furthermore, the contour line of the resist opening 7a may have a shape in which only a part of the contour line is a curved line, instead of the shape in which all the contour line is a curved line such as the circle or the ellipse. An example of such a shape of the contour line includes an oval made of one square or rectangle and two semicircles. This oval contour line includes two straight lines and two curved lines (arc lines).

As described above, the resist opening 7a in the present embodiment is formed in the resist layer 7 so that at least a part of the contour line of the resist opening 7a is a curved line and this curved line overlaps cut target patterns (the second sidewall patterns 6c to 6f). Therefore, according to the present embodiment, portions of the cut target patterns can be suppressed from being left as the long minute lines.

### Second Embodiment

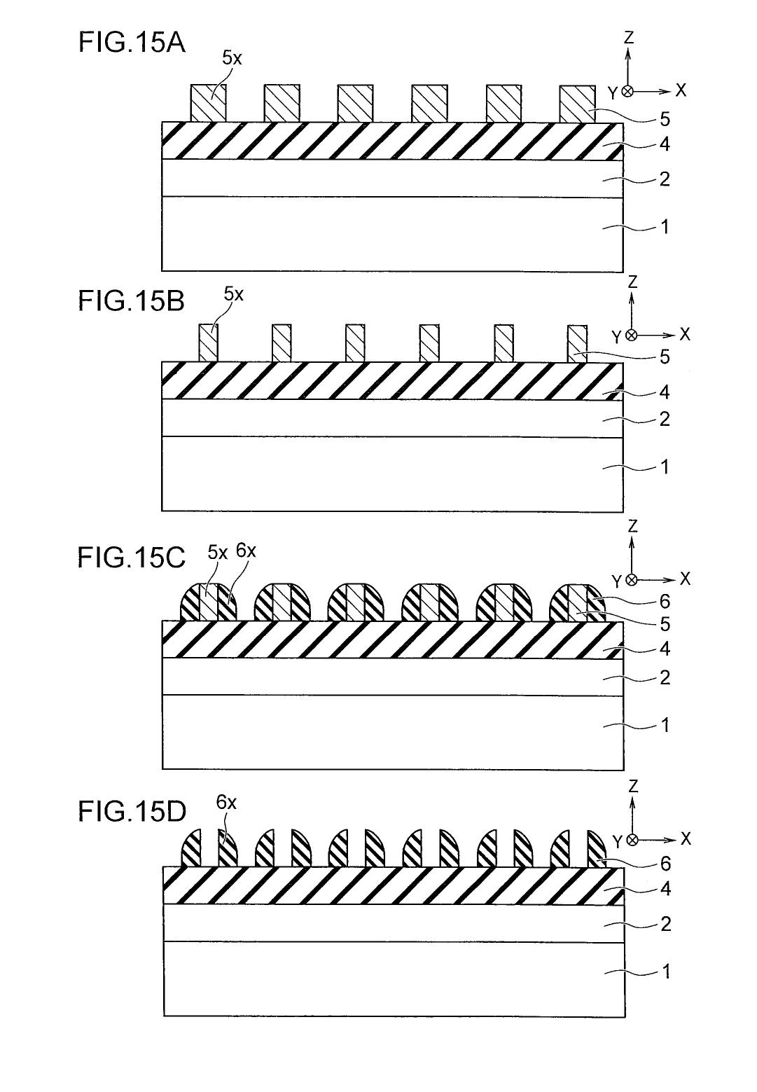

FIGS. 15A to 19B are sectional views and plan views showing a method of manufacturing a semiconductor device of a second embodiment. In the second embodiment, interconnect patterns are formed by a damascene method. Hereinafter, a description will be given of the method of the second embodiment with omitting the description of the matter common to the method of the first embodiment.

First, as shown in FIG. 15A, the base layer 2, the mask material 4 and the core material 5 are sequentially formed on the semiconductor substrate 1, and the core material 5 is processed into core material patterns 5x by lithography and etching. The character “5x” represents respective core material patterns shown in FIG. 15A (the same applies hereinafter).

Next, as shown in FIG. 15B, slimming is carried out to slim the core material patterns 5x by anisotropic etching or the like.

Next, as shown in FIG. 15C, the sidewall material 6 is deposited on the entire surface of the semiconductor substrate 1, and the sidewall material 6 is processed by anisotropic etching or the like. As a result, sidewall patterns 6x are formed on side surfaces of the core material patterns 5x.

Next, as shown in FIG. 15D, the core material patterns 5x are removed by dry etching such as the CDE with the sidewall patterns 6x being left.

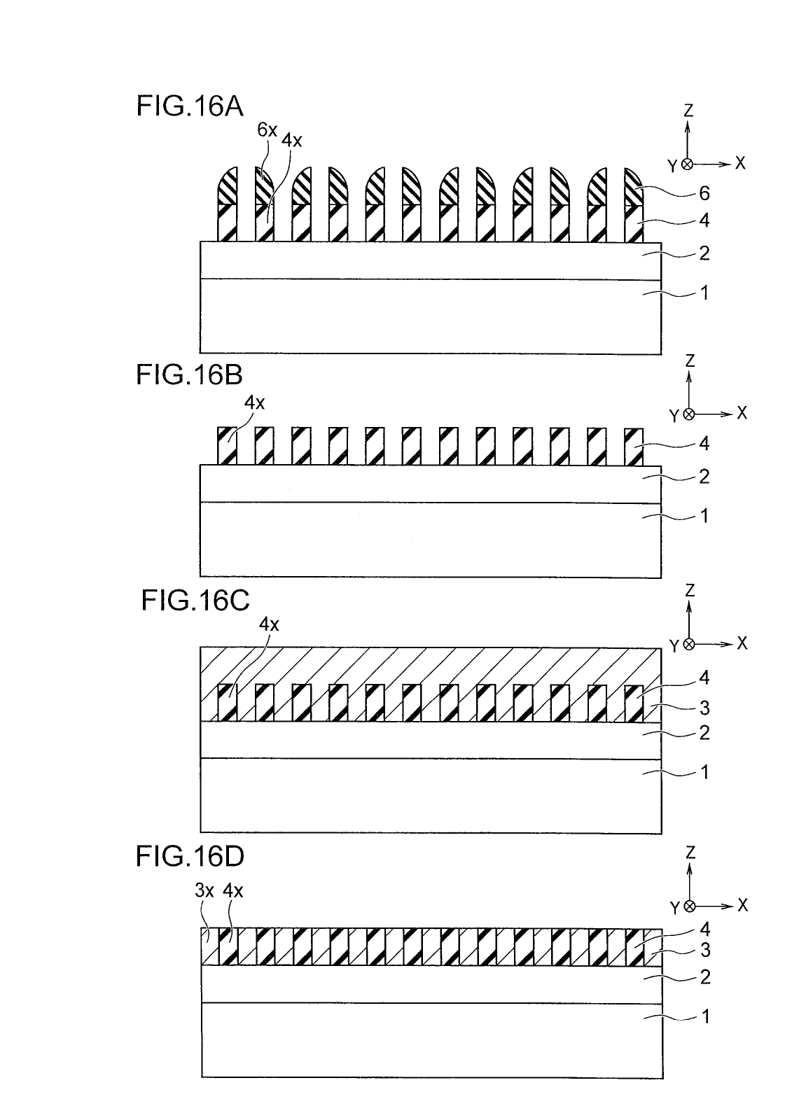

Next, as shown in FIG. 16A, the mask material 4 is etched by using the sidewall patterns 6x as a mask. As a result, the mask material 4 is processed into mask patterns 4x having the same shape as the sidewall patterns 6x.

Next, as shown in FIG. 16B, the sidewall patterns 6x are removed by wet etching or the like.

Next, as shown in FIG. 16C, an interconnect material 3 is formed on the entire surface of the semiconductor substrate 1. The interconnect material 3 is, for example, a Cu layer, a W layer or an Al layer and formed by sputtering or plating.

Next, as shown in FIG. 16D, the surface of the interconnect material 3 is planarized by chemical mechanical polishing (CMP) until the planarized surface reaches the surfaces of the mask patterns 4x. As a result, interconnect patterns 3x are formed in trenches between the mask patterns 4x.

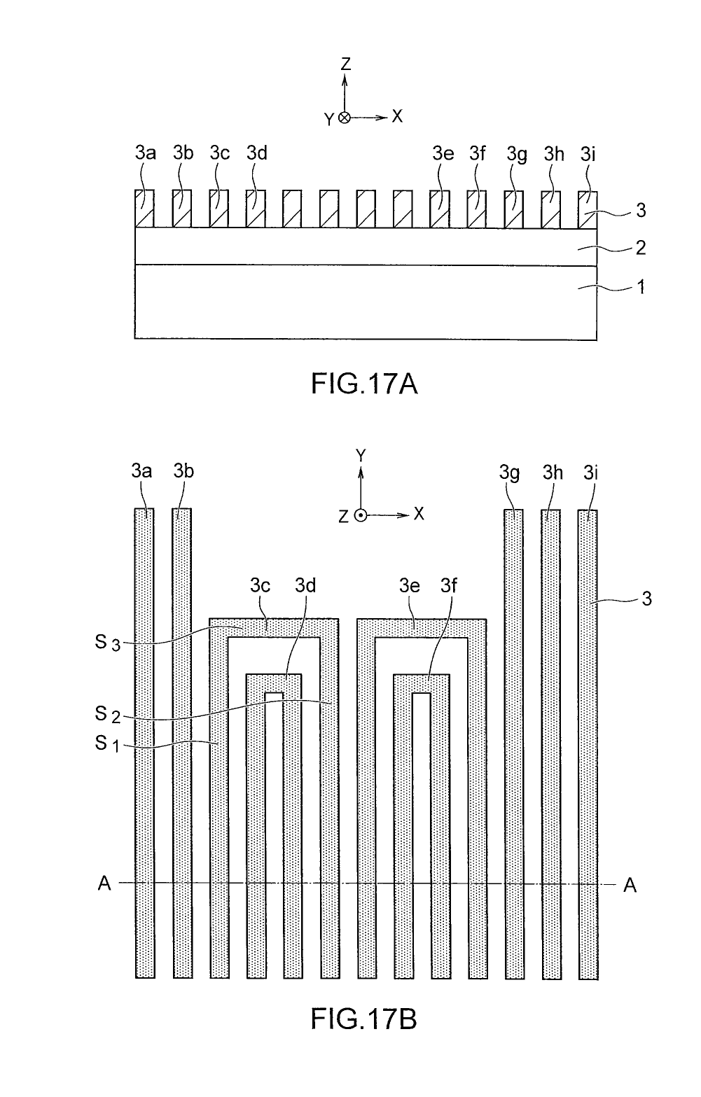

Next, as shown in FIGS. 17A and 17B, the mask patterns 4x are removed by wet etching or the like. In this way, interconnect patterns 3a to 3i are formed to have the line width less than the resolution limit of lithography (characters “3a” to “3i” are used instead of the character “3x” in FIG. 17A and subsequent figures).

The interconnect patterns 3a to 3i in the present embodiment include first interconnect patterns 3a, 3b, and 3g to 3i, and second interconnect patterns 3c to 3f adjacent to the first interconnect patterns 3a, 3b, and 3g to 3i. Each first interconnect pattern 3a, 3b, 3g, 3h, 3i includes a linear portion extending in the Y direction. Each second interconnect pattern 3c, 3d, 3e, 3f includes first and second linear portions S₁ and S₂ extending in the Y direction, and a connection portion S₃ connecting an end portion of the first linear portion S₁ and an end portion of the second linear portion S₂ with each other. Furthermore, each second interconnect pattern 3c, 3d, 3e, 3f includes another connection portion (not shown) different from the connection portion S₃, so that each second interconnect pattern 3c, 3d, 3e, 3f has a closed loop shape. The first and second interconnect patterns 3a to 3i are examples of the first and second patterns, respectively.

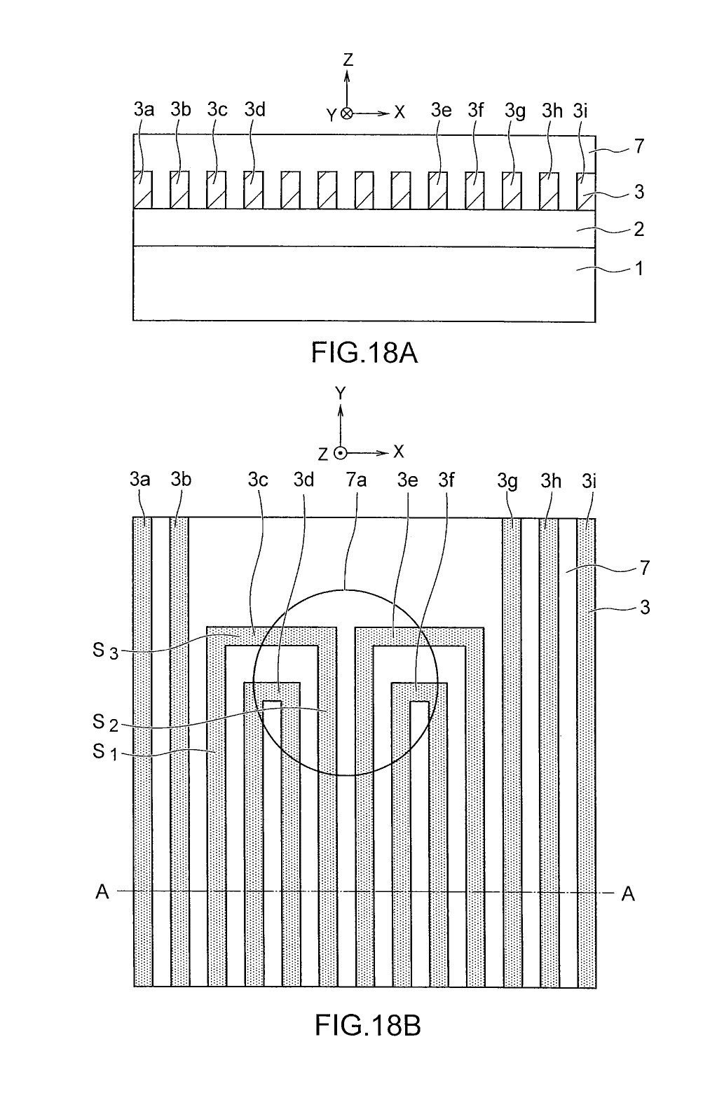

Next, as shown in FIG. 18A, the resist layer 7 is formed on the entire surface of the semiconductor substrate 1 to cover the interconnect patterns 3a to 3i with the resist layer 7. As shown in FIG. 18B, the circular resist opening 7a is then formed in the resist layer 7.

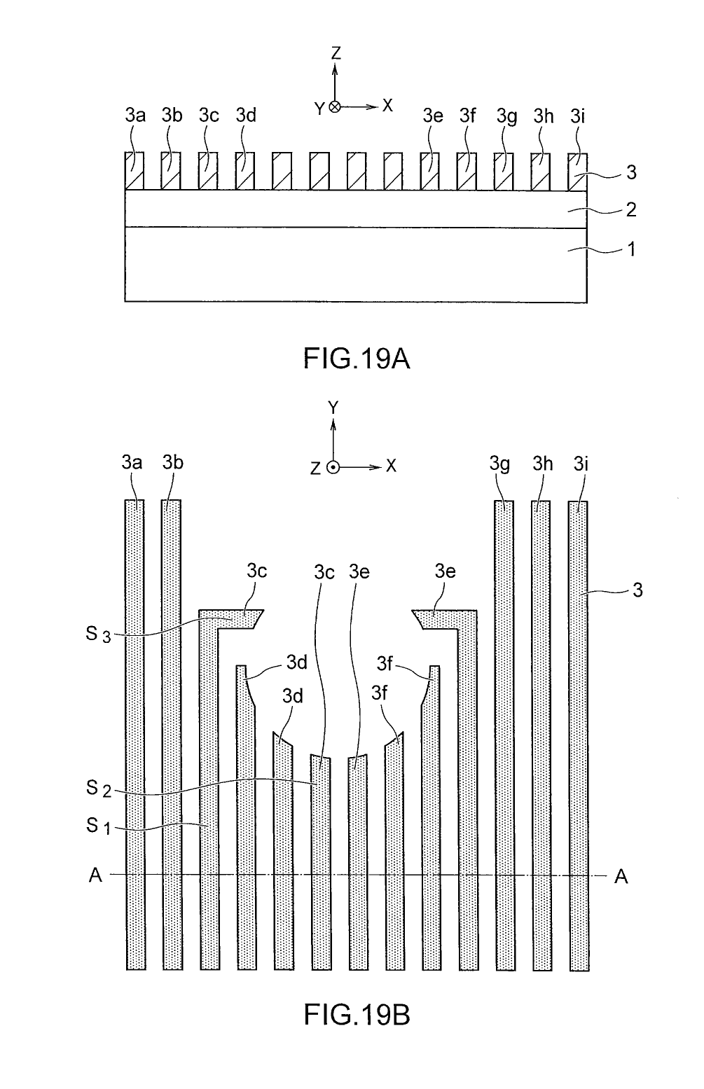

The resist opening 7a is formed so that its contour line (curved line) overlaps the second interconnect patterns 3c to 3f. As a result, each second interconnect pattern 3c, 3d, 3e, 3f is etched to have a curved cut edge by the etching described later (see FIGS. 19A and 19B).

Furthermore, the resist opening 7a is formed so that its contour line does not overlap the first interconnect patterns 3a, 3b, and 3g to 3i. Therefore, the first interconnect patterns 3a, 3b, and 3g to 3i are not etched in the etching described later (see FIGS. 19A and 19B).

Next, as shown in FIGS. 19A and 19B, the closed loops of the second interconnect patterns 3c to 3f are cut by etching using this resist layer 7. As a result, the second interconnect patterns 3c to 3f are divided into the first linear portions S₁ and the second linear portions S₂.

As described above, the resist opening 7a in the present embodiment is formed in the resist layer 7 so that at least a part of the contour line of the resist opening 7a is a curved line and this curved line overlaps cut target patterns (the second interconnect patterns 3c to 3f). Therefore, according to the present embodiment, portions of the cut target patterns can be suppressed from being left as the long minute lines.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming one or more first patterns and one or more second patterns adjacent to the first patterns on a semiconductor substrate, each first pattern including a linear portion extending in a first direction, and each second pattern including first and second linear portions extending in the first direction and a connection portion connecting an end portion of the first linear portion and an end portion of the second linear portion with each other;
forming a resist layer on the first and second patterns;
forming a resist opening in the resist layer so that at least a part of a contour line of the resist opening is a curved line and the curved line overlaps the second patterns; and
dividing the second patterns into the first and second linear portions by etching using the resist layer.

2. The method of claim 1, wherein a shape of the contour line of the resist opening is a circle or an ellipse.

3. The method of claim 2, wherein a radius of the ellipse in the first direction is longer than a radius of the ellipse in a second direction perpendicular to the first direction.

4. The method of claim 1, wherein the contour line of the resist opening has a shape which does not include a straight line parallel with the first direction.

5. The method of claim 1, wherein the resist opening is formed so that the curved line overlaps the connection portion of at least one of the second patterns.

6. The method of claim 5, wherein the at least one of the second patterns includes a nearest second pattern which is nearest to the first patterns among the second patterns.

7. The method of claim 6, wherein the resist opening is formed so that the contour line overlaps the second linear portion of the nearest second pattern and does not overlap the first linear portion of the nearest second pattern.

8. The method of claim 1, wherein the resist opening is formed so that the contour line overlaps two or more portions of each second pattern.

9. The method of claim 1, wherein at least one of the second patterns is divided into a first portion including the first linear portion and the connection portion, and a second portion including the second linear portion.

10. The method of claim 9, wherein the at least one of the second patterns includes a nearest second pattern which is nearest to the first patterns among the second patterns.

11. The method of claim 9, wherein a length of the connection portion included in the first portion after the dividing is shorter than a length of the connection portion before the dividing.

12. The method of claim 1, wherein the first and second patterns are formed by forming core material patterns on the semiconductor substrate, forming sidewall patterns on side surfaces of the core material patterns, and removing the core material patterns after forming the sidewall patterns.

13. The method of claim 12, wherein the first and second patterns are the sidewall patterns or interconnect patterns formed by using the sidewall patterns.

14. The method of claim 1, further comprising etching a layer below the first and second patterns by using the first and second patterns divided into the first and second linear portions as a mask.

15. A semiconductor device comprising:
a semiconductor substrate;
one or more first interconnect patterns disposed on the semiconductor substrate, each first interconnect pattern including a linear portion extending in a first direction; and
one or more second interconnect patterns disposed on the semiconductor substrate to be adjacent to the first interconnect patterns, each second interconnect pattern including a linear portion extending in the first direction, wherein
end portions of the one or more second interconnect patterns are positioned on the same circle or ellipse, and
at least one of the second interconnect patterns includes the linear portion and a connection portion which is connected to an end portion of the linear portion in a second direction perpendicular to the first direction.

16. The device of claim 15, wherein the at least one of the second interconnect patterns includes a nearest second interconnect pattern which is nearest to the first interconnect patterns among the second interconnect patterns.

17. The device of claim 15, wherein the one or more second interconnect patterns include a second interconnect pattern including the connection portion, and a second interconnect pattern not including the connection portion.

18. The device of claim 15, wherein widths of the end portions of the second interconnect patterns are larger than widths of portions of the second interconnect patterns other than the end portions.

19. The device of claim 15, wherein a nearest first interconnect pattern which is nearest to the second interconnect patterns among the first interconnect patterns includes a region expanding in a direction of the second interconnect patterns.

20. The device of claim 15, wherein a radius of the ellipse in the first direction is longer than a radius of the ellipse in the second direction.
